(19) United States
(12) Patent Application Publication
(10) Pub. No.: US 2015/0299897 A1
(43) Pub. Date: Oct. 22, 2015

(54) METHOD FOR FORMING AN EPITAXIAL SILICON LAYER

(71) Applicant: COMMISSARIAT A L'ENERGIE ATOMIQUE ET AUX ENERGIES ALTERNATIVES, Paris (FR)

(72) Inventors: Malek BENMANSOUR, Chambery (FR); Jean-Paul GARANDET, Le Bourget Du Lac (FR); Daniel MORVAN, Paris (FR)

(21) Appl. No.: 14/430,800

(22) PCT Filed: Sep. 23, 2013
(86) PCT No.: PCT/IB2013/058770

§ 371 Date: Jun. 17, 2015

(30) Foreign Application Priority Data
Sep. 24, 2012 (FR) 1258913

(51) Int. Cl. C30B 25/10; C30B 29/06

(52) U.S. Cl. CPC C30B 25/105; C30B 29/06

(57) ABSTRACT

The invention relates to a method for forming a crystallised silicon layer having a crystallite size higher than or equal to 100 μm, by the epitaxial growth in a vapour phase, on the surface of at least one silicon substrate, including at least the steps: (i) providing a silicon substrate having a particle size higher than or equal to 100 μm and including a metal impurities content of between 0 ppb and 1 ppm by weight; and (ii) forming the silicon layer on the surface of the substrate heated to a temperature of between 1000 and 1300° C., by decomposition of at least one silicon precursor by unit of an inductive plasma torch, the surface of the substrate for supporting the silicon layer being positioned close to the outlet of the plasma torch in step (ii).

The present invention relates to a novel process for forming an epitaxial silicon layer, of good quality and having a crystallite size of greater than or equal to 100 μm.

The photovoltaic market is experiencing a strong growth and a diversification of applications. The continuation of this growth entails being able to reduce the manufacturing costs of solar cells, which are predominantly produced from silicon. The conventional process consists in using a silicon wafer approximately 200 μm thick as basic support of the solar cell.

A reduction in the manufacturing costs of a photovoltaic cell involves a reduction in the consumption of silicon during the process for manufacturing said cell. To do this, one solution consists in depositing a thin layer of silicon of a few tens of microns on a mechanical support known as a substrate.

Numerous studies have been developed for the purpose of producing such thin layers of silicon for photovoltaic cells. For economic reasons, these layers should ideally be deposited on inexpensive substrates, with industrially accepted deposition rates, generally greater than 1 μm·min⁻¹ for reasons of productivity of the process. They should also be chemically pure with a crystalline structure characterized by grains having a size greater than 100 μm, preferentially greater than 1 mm.

The choice of the nature of substrate, and also the crystalline structure characteristics of the silicon layer deposited, depend on the temperature at which the deposition is carried out.

Thus, when the deposition is carried out at low temperature, for example by PVD or CVD, inexpensive substrates of glass or polymer type can be used. However, the layers are obtained with deposition rates of about 1 nm·min⁻¹ and the silicon deposited is amorphous or microcrystalline in nature with grains sizes ranging from 1 nm to 100 nm. For thin layers of this type, low energy conversion yields, typically at best of about about 10%, are obtained.

At higher temperature (>700° C.), for example by CVD, it becomes possible to obtain layers of polycrystalline silicon having a grain size of between 1 and 10 μm, with a deposition rate of about a few microns per minute. These deposition techniques nevertheless require the use of substrates suitable for high temperatures. Said substrates must have a good resistance to heat shocks, and a thermal expansion coefficient that is sufficiently close to silicon in order to avoid the thermomechanical stresses which occur in the layer during cooling. These criteria therefore reduce the choice of the substrate to materials of ceramic type (mullite, silica, alumina, etc.) with a high melting point, the cost of which is generally high. Furthermore, the use of these substrates causes a degradation of the purity of the deposited layers by diffusion of the impurities from the substrate to the deposited layer.

In order to obtain coarse-grain materials (size greater than 100 μm, preferentially 1 mm) which make it possible to obtain higher energy conversion yields, it has been proposed to implement epitaxy techniques based on the use of large-grain crystalline silicon substrates. For example the technology known as “Epitaxial Wafer-Equivalent” (EpiWE) [1] is based on the use of a “low-cost” strongly doped silicon substrate originating from microelectronics scrap or ideally originating from of a substrate of upgraded metallurgical grade Si (UMG-Si).

Various deposition techniques have already been proposed for producing an epitaxial silicon layer having a thickness of between 5 and 30 μm, with growth rates greater than 1 μm·min⁻¹ [2].

On the one hand, liquid phase epitaxy (LPE) techniques use a liquid bath made of up a mixture of silicon and a metallic solvent, cooling of the bath allowing deposition of the silicon by supersaturation of the mixture.

On the other hand, vapor deposition techniques (CVD or Chemical Vapor Deposition) make it possible to obtain silicon layers by thermal decomposition of a silicon-based precursor (generally SiH₄ or SiHCl₃). It is possible to obtain growth rates of several μm·min⁻¹, for substrate temperatures of 1000 to 1200° C. [2]. Unfortunately, these techniques generally require, in order to obtain layers of high quality, the use of substrates of highly pure silicon, which is generally boron-doped or phosphorus-doped (p- or n-type doped microcrystalline silicon (CZ)). In fact, when less expensive substrates, such as UMG-Si prepurified metallurgical silicon, are used, contamination of the layers formed by the impurities of the substrate occurs. It is then necessary to carry out the deposition of a barrier layer, for example of SiC, thereby increasing the complexity and the cost of the process [3]. Moreover, these gas deposition processes generally exhibit low material yields, because of the difficulty in localizing the gas stream for producing the deposits. The deposition thus occurs on the substrates, but also over the entire surface of the reactors.

Still in the vapor deposition field, another technique, that of thermal plasma chemical vapor deposition (TP-CVD), has also been proposed. It is possible, by TP-CVD, to produce layers at higher working pressures, of about 250 mbar, which makes it possible to achieve the required deposition rates, of about several μm·min⁻¹. This technique has, for example, been used for producing deposits of diamond carbon, ZnO, SiC and Si₃N₄ [4]. The TP-CVD technique has also been proposed, in a low-pressure configuration and at low temperature, for the deposition of amorphous or microcrystalline silicon layers, using an arc plasma [5]. However, the layer obtained via this process does not have the desired crystallite size. Likewise, the TP-CVD process causes diffusion of the species dissociated by the plasma from the precursors in the entire deposition chamber, which is detrimental to the material yield of the process.

Consequently, the technologies currently available do not make it possible to easily obtain thin epitaxial silicon layers having a high crystallite size, on an inexpensive basic substrate, with a deposition rate greater than 1 μm·min⁻¹ and a good material yield.

The present invention precisely aims to provide a process which satisfies the abovementioned requirements.

Thus, the present invention relates to a process for forming, by means of vapor epitaxial growth, at the surface of at least one silicon substrate, a crystalline silicon layer having a crystallite size greater than or equal to 100 μm, comprising at least the steps consisting in:

(i) providing a silicon substrate having a grain size greater than or equal to 100 μm and comprising a metal impurity content ranging from 10 ppb to 1 ppm by weight; and

(ii) forming said silicon layer at the surface of said substrate brought to a temperature of between 1000 and 1300° C., by decomposition of at least one silicon precursor by means of an inductive plasma torch,

the surface of said substrate intended to support the silicon layer being positioned, in step (ii), in proximity to the outlet of the plasma torch.

In particular, the deposition of the silicon layer is carried out by maintaining the surface to be coated of said substrate at a distance (d) of less than or equal to 10 cm from the outlet of the plasma torch.

For the purposes of the invention, the “outlet of the plasma torch” is considered to be the lower base of the plasma device or applicator, in other words the lower base of the tube, which is generally cylindrical, in which the plasma is processed.

Against all expectations, the inventors have discovered that it is possible to obtain an epitaxial silicon layer of high crystallite size and of very good crystalline quality, particularly suitable for an application in a photovoltaic cell, by positioning the substrate to be coated in the vicinity downstream of the plasma torch. Such a process is all the more surprising since it is known that the provision of heat by the torch (by convective transfer and/or electromagnetic coupling) generates temperature gradients within the substrate. As it happens, at the temperatures used according to the process, greater than 1000° C., since silicon has a plastic behavior, the temperature gradients are capable of bringing about a multiplication of the dislocation density. It could thus be expected that placing the substrate in proximity to the outlet of the torch would lead to a degradation of the properties of the material. Surprisingly, the inventors have noted that the layers formed via the process of the invention are of very good crystalline quality, in particular with dislocation densities of less than 10⁵/cm² and which may reach 10⁴/cm².

The process of the invention proves to be advantageous in several respects.

First of all, it makes it possible to obtain a crystalline silicon layer formed from crystallites having a size greater than or equal to 100 μm, in particular greater than or equal to 500 μm and more preferentially greater than or equal to 1 mm. Such a crystallographic structure advantageously ensures high energy conversion yields when it is used in a photovoltaic cell.

Moreover, the process of the invention advantageously makes it possible to dispense with the use of expensive silicon substrates. It in fact allows the use of a basic substrate made of inexpensive silicon, of upgraded metallurgical-grade silicon (UMG-Si) type. Such a silicon substrate is, for example, derived from ingots produced by directed solidification. Thus, the silicon substrate used in the process of the invention may comprise a content of metal impurities, such as Fe, Cr, Al, etc., ranging up to 1 ppm by weight.

The use, as substrates for photovoltaic applications, of substrates of UMG-Si type, although they are prepurified by directed solidification, was in no way obvious, from the viewpoint of the problem of diffusion of the metal impurities into the layer formed. Against all expectations, the inventors have discovered that the use of “low-cost” silicon substrates originating from an ingot of silicon purified by directed solidification, and the total metal impurity concentration of which is between 10 ppb and 1 ppm by weight, does not generate contamination of the epitaxial layer by the impurities of the substrate, which advantageously makes it possible to dispense with deposition of a diffusion-barrier layer.

Likewise, since the “low-cost” silicon substrates from the metallurgical industry are generally strongly doped, in particular with at least 10 ppm by weight of boron and 10 ppm by weight of phosphorus, they may advantageously serve as a rear electrode for the photovoltaic cell formed from such substrates, and therefore have an electrical function in addition to their mechanical support function.

Furthermore, the thermal plasma deposition according to the process of the invention advantageously makes it possible to achieve high epitaxial silicon layer growth rates, while at the same time increasing material yields. The plasma flow from the plasma torch results in a sizable provision of energy, which reduces the auxiliary heating requirements for achieving the high temperatures necessary for producing an epitaxial layer.

Finally, contrary to an arc plasma, the use of an inductive plasma torch makes it possible to dispense with pollution of the layer deposited by erosion of the high-voltage electrode.

Other characteristics, advantages and modes of application of the process according to the invention will emerge more clearly on reading the description which follows, given by way of nonlimiting illustration, and in particular with reference to the appended drawings, in which:

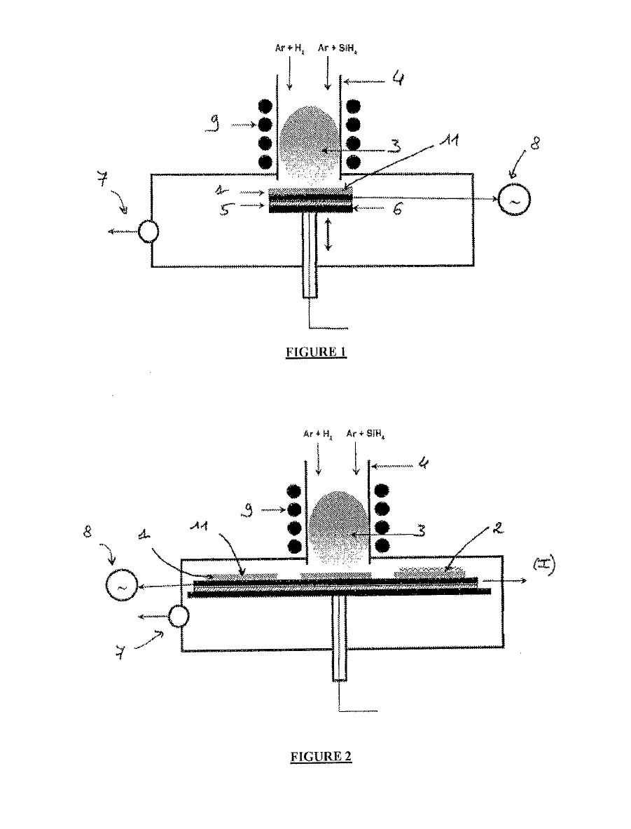

FIG. 1 represents, diagrammatically and partially, a facility suitable for implementing the process according to the invention;

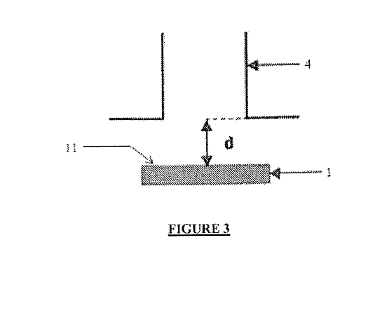

FIG. 2 represents, diagrammatically and partially, a variant of the facility of FIG. 1, enabling the continuous treatment of several substrates according to the process of the invention; and

FIG. 3 represents an enlargement of the zone in the vicinity of the plasma torch outlet in the facilities represented in FIGS. 1 and 2.

It should be noted that, in the interests of clarity, the various elements in FIGS. 1 to 3 are represented in free scale, the actual sizes of the various parts not being observed.

In the remainder of the text, the expressions “between . . . and . . . ”, “ranging from . . . to . . . ” and “varying from . . . to . . . ” are equivalent and are intended to signify that the limits are included, unless otherwise mentioned.

Unless otherwise indicated, the expression “containing/comprising a” should be understood to be “containing/comprising at least one”.

Silicon Substrate of Step (i)

In the context of the present invention, the term “substrate” refers to a solid basic structure on one of the faces of which is deposited the silicon layer according to the process of the invention.

The silicon substrate is in particular a multicrystalline silicon substrate.

According to a first of its specificities, the silicon substrate used in step (i) of the process of the invention has a grain size greater than or equal to 100 μm.

More particularly, the grain size of said substrate may be between 100 μm and 20 mm, in particular between 1 mm and 10 mm.

The average size of the silicon grains may be measured by optical microscopy or with a scanning electron microscope.

According to another of its specificities, the silicon substrate used in step (i) of the process of the invention has a metal impurity content ranging from 10 ppb to 1 ppm by weight.

In particular, said substrate may comprise metal impurities, such as Fe, Al, Ti, Cr, Cu or mixtures thereof, in a content ranging from 50 ppb to 1 ppm by weight.

These metal impurities may be more particularly iron or aluminum.

The metal impurity content may, for example, be determined by the Glow Discharge Mass Spectroscopy technique or by ICP-MS (inductively coupled plasma mass spectrometry).

As previously specified, the substrate used may be more particularly a “upgraded metallurgical grade” silicon (UMG-Si) substrate.

Such a silicon substrate may, for example, be derived from an ingot of silicon, purified by directed solidification.

The directed solidification advantageously makes it possible to reduce the contents of metal impurities present in a silicon ingot. It is generally performed by firstly making the raw material partially or totally melt, then by subjecting it to a cooling phase after thermal stabilization. The directed solidification process creates, at the end of the ingot, a surface layer, containing the impurities, that will subsequently be eliminated (scalping step).

Those skilled in the art are able to implement the conditions suitable for purification of a silicon ingot by directed solidification.

For example, such a silicon ingot, purified by directed solidification, may be obtained via a process comprising at least the steps consisting in:

(a) providing a container containing silicon in the molten state, the container having a longitudinal axis and the silicon in the molten state defining a free surface on the side opposite the bottom of the container,

(b) imposing on the silicon in the molten state conditions conducive to its solidification, comprising in particular a mixing system which makes it possible to get closer to the conditions of perfect mixing of the molten bath, which are known to be optimal for purification.

After cooling of the ingot obtained at the end of step (b), the material enriched with compounds other than silicon can be removed by cutting off the side, bottom and top parts of the ingot obtained.

The UMG-Si-type silicon ingot can then be cut into slices, according to techniques well known to those skilled in the art.

The silicon substrate used in step (i) of the process of the invention may thus have a thickness ranging from 200 to 700 μm, in particular from 300 to 500 μm.

The silicon substrate used in the process of the invention may also comprise one or more doping agents, in particular one or more P-type and/or N-type doping agents.

According to one particular embodiment, said substrate may comprise one or more P-type doping agent(s), such as, for example, aluminum (Al), gallium (Ga), indium (In) or boron (B), in particular boron.

Said P-type doping agent(s) may be present in the substrate in a content of at least 10 ppm by weight, in particular ranging from 10 to 50 ppm by weight.

According to one particular embodiment, said substrate may comprise one or more N-type doping agent(s), such as, for example, antimony (Sb), arsenic (As) or phosphorus (P), in particular phosphorus.

Said N-type doping agent(s) may be present in the substrate in a content of at least 10 ppm by weight, in particular ranging from 10 to 50 ppm by weight.

In practice, by virtue of the process for producing the basic silicon that will be used to produce the ingot, the substrate may comprise at least one P-type doping agent, in particular boron, and at least one N-type doping agent, in particular phosphorus.

According to one particular embodiment, the silicon substrate used in step (i) of the process according to the invention comprises from 10 to 50 ppm by weight of boron and from 10 to 50 ppm by weight of phosphorus.

Step (ii): Formation of the Epitaxial Silicon Layer

In a second step of the process of the invention, a silicon layer is formed at the surface of the substrate, by vapor epitaxial growth by means of an inductive plasma torch.

The surface of the substrate intended to support the epitaxial silicon layer will, in the remainder of the text, be more simply denoted “surface”.

In the remainder of the text, reference will be made to the appended FIGS. 1 to 3, which represent, diagrammatically and partially, facilities suitable for implementing the process of the invention.

The torch used according to the invention is an inductive plasma torch, i.e. an electrode-free torch, plasma being generated by high-frequency excitation of plasma gas. Any type of inductive plasma torch known to those skilled in the art may be suitable.

As previously mentioned, the use of an inductive plasma torch has, in particular compared with the use of a plasma arc torch, the advantage of not polluting the deposited layer by erosion of the electrode required for the generation of the plasma arc.

The plasma device or applicator is more particularly, for an inductive plasma torch, in the form of a tube (4), shown diagrammatically in FIG. 1 made of insulating material, for example made of quartz, intended for the formation of the plasma.

The high-frequency field for creation of the plasma is produced by a winding coiled around the tube (induction coils (9)), fed by a high-frequency generator of sufficient power.

The plasma may, for example, be generated by means of an inductively coupled radiofrequency (RF) generator, in particular of which the power ranges from 2 kW to 20 kW. The generator may operate at a frequency ranging from 1 to 20 MHz.

The tube, which is the plasma applicator, receives, in its upper part, a mixture of plasma gas(es) and of at least one silicon precursor. A plasma jet forms through the effect of the pumping of the gases, as said jet is directed onto the substrate.

For example, as represented in FIG. 1, a mixture of plasma gases (for example a mixture of argon and hydrogen) is injected via a first route, while a 2nd route makes it possible to inject the silicon precursor gas (for example SiH₄) and optionally a plasma gas (for example argon).

The term “plasma gas(es)” is intended to denote the gas or gas mixture within which the plasma is created. The plasma gases are generally chosen from argon, helium, neon and hydrogen and mixtures thereof.

According to one particular embodiment, the plasma gas according to the invention advantageously comprises argon, preferably a mixture of argon and hydrogen, the proportion of hydrogen in the mixture being more particularly between 2% and 30% by volume, in particular between 5% and 20% by volume.

For the purposes of the invention, the term “silicon precursor” is intended to mean a compound capable of releasing silicon by decomposition within the plasma.

The silicon precursor according to the invention may be chosen from silane (SiH₄); polysilanes such as Si₂H₆ and Si₃H₈, halosilanes of formula SiXₙH₄₋ₙ with X=Cl, Br or F, and n less than or equal to 4, in particular SiHBr₃ or SiHCl₃; and organosilanes, in particular SiCl₃CH₃ or triethylsilane; and mixtures thereof.

Preferably, the silicon precursor is chosen from silane and halosilanes. It is in particular silane or trichlorosilane (TCS).

Said silicon precursor(s) may represent from 1% to 10% of the total gas volume of the plasma gases and precursors feeding the torch.

According to one particular embodiment, the plasma is formed from a mixture of argon, hydrogen and one or more gaseous precursors of silicon, in particular silane.

Of course, the device may conventionally comprise means not represented in FIG. 1, for controlling the torch feed flow rate, for example by means of valves.

According to one particular embodiment, the gas flow rate of the plasma torch (4) in step (ii) is between 0.1 and 10 l·min⁻¹, in particular between 1 and 5 l·min⁻¹.

The plasma torch (4) may more particularly operate at a pressure ranging from 50 to 400 mbar, preferably ranging from 150 to 300 mbar.

The deposition of silicon by means of the inductive plasma torch may be carried out within a chamber, the pressure of which is controlled by means of a pumping device (7), in order to purge the chamber or to improve the gas circulation.

As previously specified, the substrate is, during step (ii), maintained at a temperature of between 1000 and 1300° C.

In particular, said substrate is maintained, during step (ii), at a temperature of between 1100° C. and 1200° C.

The substrate may be heated prior to its exposure to the plasma torch in order to reach the desired temperature. Preferably, the temperature of the substrate is kept constant throughout formation of the epitaxial silicon layer.

The temperature of said substrate in step (ii) may be obtained by heating using a heating means distinct from said plasma torch, for example using a graphite resistance heating device.

By way of example, on the device represented in FIG. 1, the substrate (1) is placed on a substrate holder equipped with a graphite heating device (6), from which the substrate is separated by a layer of electrical insulation (5).

As previously mentioned, according to one characteristic of the process of the invention, the surface of the substrate on which the epitaxial layer must be formed is positioned in proximity to the plasma torch outlet.

The surface (11) of the substrate is more particularly maintained, in step (ii), at a distance (d) of less than or equal to 10 cm from the plasma torch outlet.

As represented in FIG. 3, this distance (d) is measured between the lower base of the tube (4), which is generally cylindrical, in which the plasma is processed (and not the end downstream of the induction coil which could be mobile), and the surface (11) of the substrate.

In particular, this distance (d) is non-zero.

According to one particular embodiment, the distance (d) may be between 1 and 10 cm, and more particularly between 3 and 6 cm.

The duration of exposure of the surface (11) of the substrate to the plasma is of course adjusted from the viewpoint of the thickness of the epitaxial silicon layer desired.

According to one particular embodiment, the exposure of the surface (11) to the plasma in step (ii) according to the invention may be carried out for a period ranging from 5 minutes to 1 hour, preferably from 10 minutes to 30 minutes.

The rate of deposition of the silicon layer (2) depends of course on the degree of dissociation of the silicon precursor into free radicals.

According to one particular embodiment, said silicon substrate (1) may be polarized during step (ii) with a negative voltage, in particular with a voltage ranging from −200 volts to −10 volts.

This polarization may be carried out using a direct or alternating current source (8), as represented diagrammatically in FIG. 1.

Such a polarization of the substrate advantageously makes it possible to increase the growth rate of the epitaxial silicon layer by promoting ion transport in the limiting layer between the plasma and the surface of the substrate.

Advantageously, the rate of deposition of the silicon layer (2) in step (ii) may be at least 1 μm·min⁻¹, in particular greater than or equal to 2 μm·min⁻¹, and more particularly between 2 and 10 μm·min⁻¹.

According to one implementation variant, it is possible to continuously treat several substrates by placing them on a translation device capable of successively exposing the surface (11) of each of said substrates to the plasma of the torch (4).

A facility for carrying out such an implementation variant is represented diagrammatically in FIG. 2, where three substrates are successively exposed to the plasma (3), by means of a translational movement of the substrate holder in the direction (I).

It is understood that the parameters, for the deposition of an epitaxial silicon layer at the surface of each of the substrates according to the process of the invention, that have been previously defined, in particular in terms of temperature of the substrate and positioning of the surface of the substrate relative to the torch outlet, are adhered to during the exposure of each of the substrates to the plasma.

Once the silicon layer (2) has formed at the surface of the substrate (1), the temperature of the substrate is preferably gradually lowered to ambient temperature, so as to avoid heat shocks.

The substrate may be more particularly maintained under an argon atmosphere until ambient temperature is reached, in order to avoid surface oxidations when the assembly is recovered.

Characteristics of the Epitaxial Layer (2)

As previously specified, the crystalline silicon layer (2), obtained at the end of step (ii) of the process of the invention, advantageously has a crystallite size of greater than or equal to 100 μm.

More particularly, the size of the crystallites of said layer (2) may be greater than or equal to 500 μm, preferably greater than or equal to 1 mm.

This size may be measured by optical microscopy or with a scanning electron microscope.

The silicon layer (2) obtained at the end of step (ii) of the process of the invention may have a thickness ranging from 10 to 100 microns, in particular from 20 to 40 microns.

Advantageously, as previously mentioned, a silicon layer (2) obtained according to the process of the invention is of good crystalline quality. It in particular has a dislocations density of less than or equal to 10⁵/cm², in particular less than 10⁴/cm².

The dislocation density may be measured using the “etch pit” technique, corresponding to a method for revealing etch pits in acidic or basic solution.

According to one particular embodiment of the invention, the silicon layer (2) obtained at the end of step (ii) comprises a metal impurity content ranging from 10 ppb to 100 ppb by weight.

The metal impurity content may be measured using any technique known to those skilled in the art. It may, for example, be evaluated by DLTS (Deep Level Transient Spectroscopy).

This technique, known to those skilled in the art, consists of the analysis of the emission and capture of the traps associated with variations in the capacitance of a p-n junction or of a Schottky diode.

It can also be measured by ICP-MS (inductively coupled plasma mass spectrometry).

According to one particular embodiment, the layer (2) formed at the end of step (ii) may be subjected to a subsequent step of extraction of the impurities via an external gettering effect.

This extraction step aims to remove the metal impurities from the body of a silicon substrate so as to confine them at the surfaces thereof, where they can no longer have an influence on the operation of the photovoltaic cells fabricated from this substrate.

The extraction by an external gettering effect is in particular described in the document “Mechanisms and computer modelling of transition element gettering in silicon” by Schroder et al., Solar Energy Materials & Solar Cells 72 (2002) 299-313.

Preferably, this step of extraction by an external gettering effect is performed by phosphorus diffusion. Such a process not only makes it possible to extract the metal impurities, but is also a step required for photovoltaic cell p-n junction formation.

The invention will now be described by means of the following example, given of course by way of nonlimiting illustration of the invention.

### EXAMPLE

The thin layer of silicon is obtained in an experimental device consisting of a stainless steel chamber cooled by water, of a cold-cage plasma torch (4) and of a substrate holder also cooled with water.

(i) UMG Silicon Substrate

The substrate (1) is a UMG silicon substrate having a thickness of 400 μm and an average grain size of 8 mm. It comprises a metal impurities content of 500 ppb, a boron content of 30 ppm and a phosphorus content of 10 ppm.

(ii) Thermal Plasma Chemical Vapor Deposition

The UMG silicon substrate is placed on the substrate holder equipped with a graphite resistance heating device (6) in order to reach temperatures of about 1100° C. The temperature is controlled using a thermocouple coupled to an electric generator.

The pressure of the chamber is lowered to 1 mbar by means of a pumping device (7). At this pressure, the plasma discharge is initiated by means of an RF generator operating at a frequency of 4 MHz and a power of 10 kW.

It is possible to maintain the working pressure (average pressure in the deposition chamber) at 200 mbar through the gradual introduction of argon at a flow rate of 3 l·min⁻¹.

When this pressure is reached, the UMG silicon substrate (1) is brought into contact with the plasma flow (3) at a distance (d) between the surface (11) to be coated and the torch outlet of 2 cm.

Once the height (d) has been fixed and the temperature of the substrate has been stabilized at 1100° C., the introduction of hydrogen and silane is begun. The hydrogen represents 10% of the mixture, while the SiH₄ content is fixed at 3% of the gas volume.

In order to increase the degree of dissociation of the silane and, consequently, the number of free radicals, the silicon substrate is negatively polarized by means of the polarization device (8). A polarization of −50 volts is then applied.

The surface (11) of the substrate is exposed to the plasma for a period of 15 minutes.

When the silicon layer is produced, the introduction of the reactive gases, hydrogen and silane, is interrupted and the substrate is gradually removed from the plasma jet either by vertical translation downward or by horizontal translation. In order to avoid heat shocks, the temperature of the substrate is gradually lowered at a rate of 10° C.min⁻¹ by decreasing the external heating power. The substrate is maintained under an argon atmosphere until ambient temperature is reached in order to avoid surface oxidations when the assembly is recovered.

Result

The silicon layer formed has a thickness of 30 μm.

It is formed from crystallites having a size, measured by SEM, of approximately 5 mm.

It has a metal impurity content, measured by ICP-MS (inductively coupled plasma mass spectrometry), of approximately 10 ppb and a dislocation density, measured by means of etch pits, of 10⁴/cm².

### REFERENCES

[1] Mitchell et al., Solar Energy Materials & Solar Cells, 95, (2011), 1163-1167;
[2] Poortmans et al., Thin Film Solar Cells, Fabrication, Characterization and Applications, Chp. 1: Epitaxial thin-film crystalline Si solar cells on low-cost Si carriers, Wiley Series in Materials for Electronic & Optoelectronic Applications, 2006;
[3] Reber et al., Crystalline silicon thin-film solar cells—Recent results at Fraunhofer ISE, Solar Energy, Volume 77, Issue 6, 2004, 865-875;
[4] Gindrat et al., Plasma Spray-CVD: A new thermal Spray process to produce thin films from liquid or gaseous precursors, Journal of Thermal Spray Technology, 882—Volume 20(4) June 2011;
[5] Smit et al., Fast deposition of microcrystalline silicon with an expanding thermal plasma, Journal of Non-Crystalline Solids, 299-302, (2002), 98-102.

1-17. (canceled)

18. A process for forming, by means of vapor epitaxial growth, at the surface of at least one silicon substrate, a crystalline silicon layer having a crystallite size greater than or equal to 100 μm, comprising at least the steps:
(i) providing a silicon substrate having a grain size greater than or equal to 100 μm and comprising a metal impurity content ranging from 10 ppb to 1 ppm by weight; and
(ii) forming said silicon layer at the surface of said substrate brought to a temperature of between 1000 and 1300° C., by decomposition of at least one silicon precursor by means of an inductive plasma torch,
the surface of said substrate intended to support the silicon layer being positioned, in step (ii), in proximity to the plasma torch outlet.

19. The process as claimed in claim 18, wherein said surface of the substrate is maintained, during step (ii), at a distance of less than or equal to 10 cm from the plasma torch outlet.

20. The process as claimed in claim 18, wherein said surface of the substrate is maintained, during step (ii), at a distance ranging from 1 to 10 cm from the torch outlet.

21. The process as claimed in claim 18, wherein said surface of the substrate is maintained, during step (ii) at a distance ranging from 3 to 6 cm from the torch outlet.

22. The process as claimed in claim 18, wherein the substrate is maintained, during step (ii), at a temperature of between 1100° C. and 1200° C.

23. The process as claimed in claim 18, wherein the temperature of said substrate in step (ii) is obtained by heating using a heating means distinct from said plasma torch.

24. The process as claimed in claim 18, wherein the temperature of said substrate in step (ii) is obtained by heating using a graphite resistance heating device.

25. The process as claimed in claim 18, wherein said substrate has a metal impurity content ranging from 50 ppb to 1 ppm by weight.

26. The process as claimed in claim 18, wherein said substrate comprises one or more P-type doping agent(s).

27. The process as claimed in claim 26, wherein said P-type doping agent is boron.

28. The process as claimed in claim 26, wherein said P-type doping agents are present in a content of at least 10 ppm by weight.

29. The process as claimed in claim 26, wherein said P-type doping agents are present in a content ranging from 10 to 50 ppm by weight.

30. The process as claimed in claim 18, wherein said substrate comprises one or more N-type doping agent(s).

31. The process as claimed in claim 30, wherein said N-type doping agent is phosphorus.

32. The process as claimed in claim 30, wherein said N-type doping agents are present in a content of at least 10 ppm by weight.

33. The process claimed in claim 30, wherein said N-type doping agents are present in a content ranging from 10 to 50 ppm by weight.

34. The process as claimed in claim 18, wherein the size of the grains of said substrate is between 100 μm and 20 mm.

35. The process as claimed in claim 18, wherein size of the grains of said substrate is between 1 mm and 10 mm.

36. The process as claimed in claim 18, wherein said substrate has a thickness ranging from 200 to 700 μm.

37. The process as claimed in claim 18, wherein said substrate has a thickness ranging from 300 to 500 μM.

38. The process as claimed in claim 18, wherein the plasma torch in step (ii) operates at a pressure ranging from 50 to 400 mbar.

39. The process as claimed in claim 18, wherein the gas within which the plasma is created in step (ii) comprises argon.

40. The process as claimed in claim 18, wherein the gas within which the plasma is created in step (ii) comprises a mixture of argon and hydrogen.

41. The process as claimed in claim 18, wherein said silicon precursor is chosen from silane, polysilanes, halosilanes of formula SiXₙH₄₋ₙ with X=Cl, Br or F, and n less than or equal to 4; and organosilanes, and mixtures thereof.

42. The process as claimed in claim 18, wherein said silicon precursor is silane or trichlorosilane.

43. The process as claimed in claim 18, wherein the gas flow rate of the plasma torch in step (ii) is between 0.1 and 10 l·min⁻¹.

44. The process as claimed in claim 18, wherein said silicon substrate is negatively polarized during step (ii).

45. The process as claimed in claim 18, wherein the silicon layer obtained at the end of step (ii) has a crystallite size greater than or equal to 500 μm.

46. The process as claimed in claim 18, wherein the silicon layer obtained at the end of step (ii) has a crystallite size greater than or equal to 1 mm.

47. The process as claimed in claim 18, wherein the silicon layer obtained at the end of step (ii) has a dislocation density of less than or equal to 10⁵/cm².

48. The process as claimed in claim 18, wherein the silicon layer obtained at the end of step (ii) has a dislocation density of less than 10⁴/cm².

49. The process as claimed in claim 18, wherein the layer formed at the end of step (ii) is subjected to a subsequent step of extraction of the impurities via an external gettering effect.
